(19) United States
(12) Patent Application Publication
(10) Pub. No.: US 2026/0331162 A1
(43) Pub. Date: Oct. 22, 2026

(54) MEMORY DEVICE, CONTROL METHOD, MEMORY SYSTEM, AND COMPUTER DEVICE

(71) Applicant: YANGTZE MEMORY TECHNOLOGIES CO., LTD., Wuhan (CN)

(72) Inventors: Danyang LI, Wuhan (CN); ZhiChao DU, Wuhan (CN); Bin LIAO, Wuhan (CN)

(21) Appl. No.: 19/289,829

(22) Filed: Aug. 4, 2025

(30) Foreign Application Priority Data
Apr. 21, 2025 (CN) 2025105029447

(51) Int. Cl. G11C 11/4091; G11C 11/4093; G11C 11/4096

(52) U.S. Cl. CPC G11C 11/4091; G11C 11/4093; G11C 11/4096

(57) ABSTRACT

A memory device includes a memory array and a peripheral circuit which are stacked together, wherein the memory array includes a plurality of memory banks, the memory bank includes a plurality of memory blocks. The peripheral circuit includes a plurality of bit line sense amplifiers and a first driving circuit connected to the plurality of bit line sense amplifiers, wherein the first driving circuit includes a first sub circuit and at least one second sub circuit, wherein the first sub circuit includes a first level shifter, the second sub circuit includes a first inverter, and the second sub circuit overlaps with a memory block of the plurality of memory blocks in a stacking direction.

### CROSS-REFERENCE TO RELATED APPLICATIONS

The present disclosure claims priority to Chinese Patent Application No. 2025105029447, which was filed Apr. 21, 2025, and is hereby incorporated herein by reference in its entirety.

### TECHNICAL FIELD

The present disclosure relates to the field of storage technology, and particularly to a memory device, a control method, a memory system, and a computer device.

### BACKGROUND

With the development of storage technology, the storage performance and density of a memory have been greatly improved.

A memory generally includes a peripheral circuit and a memory array. The peripheral circuit includes a bit line sense amplifier and a corresponding driving circuit. The memory array includes a plurality of memory banks, and each memory bank includes a plurality of memory blocks, wherein the driving circuit is configured to drive the bit line sense amplifier to perform processing on data in memory blocks, such as reading, refreshing, etc.

### SUMMARY

Implementations of the present disclosure provide a memory device, a control method, a memory system, and a computer device, which may improve the storage density of the memory device. The technical approaches are as follows:

In a first aspect, a memory device is provided. The memory device comprises a memory array and a peripheral circuit which are stacked together. The memory array comprises a plurality of memory banks, wherein a memory bank of the plurality of memory banks comprises a plurality of memory blocks. The peripheral circuit comprises a plurality of bit line sense amplifiers and a first driving circuit connected to the plurality of bit line sense amplifiers, wherein the first driving circuit comprises a first sub circuit and at least one second sub circuit, wherein the first sub circuit comprises a first level shifter, the second sub circuit comprises a first inverter, and the second sub circuit overlaps with a memory block of the plurality of memory blocks in a stacking direction.

In some implementations, the first sub circuit overlaps with a first region in the memory array in the stacking direction, and the first region is a region between the memory banks.

In some implementations, the at least one second sub circuit comprises a plurality of second sub circuits. Input terminals of the plurality of second sub circuits are connected to an output terminal of the first sub circuit, respectively, and an output terminal of each of the second sub circuits is connected to a driving terminal of a bit line sense amplifier of the plurality of bit line sense amplifiers.

In some implementations, for the plurality of bit line sense amplifiers connected to the same first driving circuit, memory blocks connected to the plurality of bit line sense amplifiers are memory blocks located in the same row in the memory bank.

In some implementations, the peripheral circuit further comprises a second driving circuit connected to the plurality of bit line sense amplifiers, wherein a bit line sense amplifier of the plurality of bit line sense amplifiers comprises a first sensing unit and a second sensing unit, the first driving circuit is configured to drive the first sensing unit, and the second driving circuit is configured to drive the second sensing unit; and the second driving circuit comprises a third sub circuit and at least one fourth sub circuit, wherein the third sub circuit comprises a second level shifter, and the fourth sub circuit comprises a second inverter, wherein a control terminal of the first level shifter comprised in the first driving circuit is connected to a control terminal of the second inverter comprised in the second driving circuit.

In some implementations, the first driving circuit is configured so that before a first time point, the first level shifter receives a first high level, and the first inverter receives a low level to cause the first inverter to output the first high level, wherein the first time point is a time point when a sensing stage switches to a pre-charging stage; and after the first time point, both the first level shifter and the first inverter receive the low level to cause the first inverter to output a second high level, wherein the first high level is higher than the second high level.

In some implementations, the first sub circuit further comprises a first signal processing unit, wherein an input terminal of the first signal processing unit is connected to an output terminal of the first level shifter, and the first signal processing unit comprises a pair of transistors in parallel. The second sub circuit further comprises a second signal processing unit and a third signal processing unit, wherein an input terminal of the second signal processing unit and a first input terminal of the third signal processing unit are connected to an output terminal of the first signal processing unit, an output terminal of the second signal processing unit is connected to a second input terminal of the third signal processing unit, an output terminal of the third signal processing unit is connected to an input terminal of the first inverter, the second signal processing unit comprises a pair of transistors in parallel, and the third signal processing unit comprises two pairs of transistors, each pair of which has transistors in parallel.

In some implementations, the second sub circuit further comprises a first signal processing unit, a second signal processing unit, and a third signal processing unit. An input terminal of the first signal processing unit is connected to an output terminal of the first level shifter in the first sub circuit, an input terminal of the second signal processing unit and a first input terminal of the third signal processing unit are connected to an output terminal of the first signal processing unit, an output terminal of the second signal processing unit is connected to a second input terminal of the third signal processing unit, an output terminal of the third signal processing unit is connected to an input terminal of the first inverter, the first signal processing unit comprises a pair of transistors in parallel, the second signal processing unit comprises a pair of transistors in parallel, and the third signal processing unit comprises two pairs of transistors, each pair of which has transistors in parallel.

In some implementations, the memory device comprises a dynamic random access memory (DRAM).

In a second aspect, a method of controlling a memory device is provided. The memory device comprises a memory array and a peripheral circuit, wherein the memory array comprises a plurality of memory banks, and a memory bank of the plurality of memory banks comprises a plurality of memory blocks. The peripheral circuit comprises bit line sense amplifiers connected to the plurality of memory blocks, respectively, and a first driving circuit connected to the bit line sense amplifiers, wherein the first driving circuit comprises a first sub circuit and at least one second sub circuit, wherein the first sub circuit comprises a first level shifter, and the second sub circuit comprises a first inverter; and wherein the method comprises: before a first time point, the first level shifter receiving a first high level and the first inverter receiving a low level to cause the first inverter to output the first high level, wherein the first time point is a time point when a sensing stage switches to a pre-charging stage; and after the first time point, both the first level shifter and the first inverter receiving the low level to cause the first inverter to output a second high level, wherein the first high level is higher than the second high level.

In some implementations, the first sub circuit further comprises a first signal processing unit, wherein an input terminal of the first signal processing unit is connected to an output terminal of the first level shifter, and the first signal processing unit comprises a pair of transistors in parallel. The second sub circuit further comprises a second signal processing unit and a third signal processing unit, wherein an input terminal of the second signal processing unit and a first input terminal of the third signal processing unit are connected to an output terminal of the first signal processing unit, an output terminal of the second signal processing unit is connected to a second input terminal of the third signal processing unit, an output terminal of the third signal processing unit is connected to an input terminal of the first inverter, the second signal processing unit comprises a pair of transistors in parallel, and the third signal processing unit comprises two pairs of transistors, each pair of which has transistors in parallel.

In some implementations, the method further comprises: before a second time point, the first level shifter receiving the low level to cause the second signal processing unit to output the first high level, and the third signal processing unit to output the second high level, wherein the second time point is within a row activation stage; and after the second time point, the first level shifter receiving the first high level to cause the second signal processing unit to output the low level, and the third signal processing unit to output the first high level.

In some implementations, the first inverter comprises a first input terminal and a second input terminal, wherein the first input terminal is connected to the output terminal of the third signal processing unit.

In some implementations, before the first time point, the first level shifter receiving the first high level and the first inverter receiving the low level to cause the first inverter to output the first high level, comprises: before the first time point, the first level shifter receiving the first high level to cause the third signal processing unit to output the first high level to the first input terminal; and the first inverter receiving the low level through the second input terminal and outputting the first high level in response to receiving the first high level at the first input terminal.

In some implementations, the first level shifter receiving the first high level to cause the third signal processing unit to output the first high level to the first input terminal, comprises: the first level shifter receiving the first high level and outputting the first high level to the first signal processing unit; the first signal processing unit outputting the low level to the input terminal of the second signal processing unit in response to the input first high level; the second signal processing unit outputting the first high level to an input terminal of the third signal processing unit in response to the input low level; and the third signal processing unit outputting the first high level to the first input terminal in response to the input first high level.

In some implementations, after the first time point, both the first level shifter and the first inverter receiving the low level to cause the first inverter to output a second high level, comprises: after the first time point, the first level shifter receiving the low level to cause the third signal processing unit to output the second high level to the first input terminal; and the first inverter receiving the low level through the second input terminal and outputting the second high level in response to receiving the second high level at the first input terminal.

In some implementations, the first level shifter receiving the low level to cause the third signal processing unit to output the second high level to the first input terminal, comprises: the first level shifter receiving the low level and outputting the low level to the first signal processing unit; the first signal processing unit outputting the first high level to the input terminal of the second signal processing unit in response to the input low level; the second signal processing unit outputting the low level to the input terminal of the third signal processing unit in response to the input first high level; and the third signal processing unit outputting the second high level to the first input terminal in response to the input low level.

In some implementations, the method further comprises: before a third time point, the first level shifter receiving the first high level and the first inverter receiving the first high level to cause the first inverter to output the low level, wherein the third time point is a time point when the row activation stage switches to the sensing stage; and after the third time point, the first level shifter receiving the first high level and the first inverter receiving the low level to cause the first inverter to output the first high level.

In a third aspect, a memory system is provided. The memory system comprises a memory device as described above in the first aspect, and a controller coupled to the memory device and configured to control the memory device.

In a fourth aspect, a computer device is provided. The computer device comprises a processor and a memory system as described above in the third aspect.

The technical approaches provided by the present disclosure have the advantageous effects as described below. In the present disclosure, the drive circuit of the bit line sense amplifier is divided into a first sub circuit comprising a level shifter and a second sub circuit comprising an inverter, wherein the second sub circuit is located in a region overlapping with the memory block. Therefore, after the second sub circuit is split from the driving circuit, the remaining first sub circuit occupies a smaller area as compared with the entire driving circuit disposed opposite to the region between the memory banks, so that the region between the memory banks may be reduced, and the density of the memory banks in the memory device may be improved.

### BRIEF DESCRIPTION OF THE DRAWINGS

In order to provide a clearer explanation of the technical solutions in implementations of the present disclosure, a brief introduction will be given to the drawings required for the description of the implementations. It is apparent that the drawings described below are only some implementations of the present disclosure. For those skilled in the art, other drawings may be obtained based on these drawings without creative labor.

FIG. 1 is a schematic structural diagram of a memory device provided in an implementation of the present disclosure;

FIG. 2 is a schematic structural diagram of a memory array provided in an implementation of the present disclosure;

FIG. 3 is a schematic plan view of a memory array provided in an implementation of the present disclosure;

FIG. 4 is a schematic plan view of a memory block partially overlapping with a peripheral circuit provided in an implementation of the present disclosure;

FIG. 5 is a schematic diagram of a bit line sense amplifier provided in an implementation of the present disclosure;

FIG. 6 is a schematic diagram of a driving circuit for a bit line sense amplifier provided in an implementation of the present disclosure;

FIG. 7 is a signal schematic diagram of a driving circuit for a bit line sense amplifier provided in an implementation of the present disclosure;

FIG. 8 is a schematic structural diagram of a memory device provided in an implementation of the present disclosure;

FIG. 9 is a schematic structural diagram of a driving circuit provided in an implementation of the present disclosure;

FIG. 10 is a schematic structural diagram of a driving circuit provided in an implementation of the present disclosure;

FIG. 11 is a schematic structural diagram of a driving circuit provided in an implementation of the present disclosure;

FIG. 12 is a schematic structural diagram of a driving circuit provided in an implementation of the present disclosure;

FIG. 13 is a flowchart of a control method provided in an implementation of the present disclosure;

FIG. 14 is a schematic structural diagram of a driving circuit provided in an implementation of the present disclosure;

FIG. 15 is a signal schematic diagram of a driving circuit for a bit line sense amplifier provided in an implementation of the present disclosure;

FIG. 16 is a schematic structural diagram of a driving circuit provided in an implementation of the present disclosure;

FIG. 17 is a schematic structural diagram of a memory system provided in an implementation of the present disclosure; and

FIG. 18 is a schematic structural diagram of a computer device provided in an implementation of the present disclosure.

### DETAILED DESCRIPTION

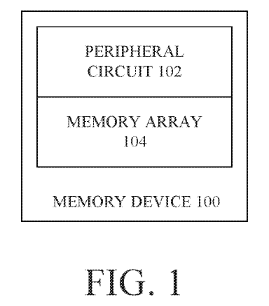

FIG. 1 is a schematic structural diagram of a memory device 100 provided in an implementation of the present disclosure. As shown in FIG. 1, the memory device 100 may include a peripheral circuit 102 and a memory array 104. In one example, the peripheral circuit 102 and the memory array 104 may be formed on different substrates and then connected together by bonding to form the memory device 100.

The peripheral circuit 102 may include various digital, analog, and/or mixed signal circuits for operating the memory array 104. For example, the peripheral circuit 102 may include one or more page buffers, decoders (such as a row decoder and a column decoder), a sense amplifier, drivers (such as a word line driver, a pre-charging voltage driver, and a discharging voltage driver), input/output (I/O) circuits, and so on.

The memory array 104 includes word lines, bit lines, and a plurality of memory cells. In one example, a memory cell may be a dynamic random-access memory (DRAM) memory cell, including a transistor and a capacitor. In the DRAM memory cell, the stored binary data "1" or "0" may be represented by the amount of charges stored in the capacitor. The transistor is configured to control the connection between the capacitor and a bit line, and is triggered to turn on or off by a signal from a word line.

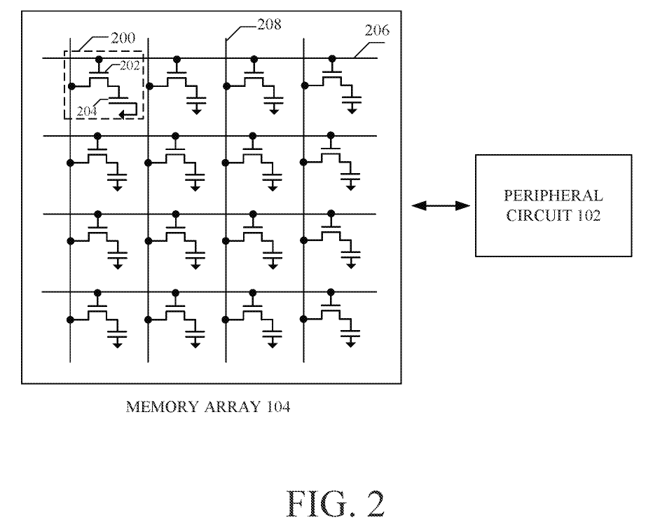

FIG. 2 is a schematic structural diagram of a memory array 104 provided in an implementation of the present disclosure. As shown in FIG. 2, each memory cell 200 in the memory array 104 may be a DRAM memory cell, including a transistor 202 and a capacitor 204. The gate of the transistor 202 may be coupled to the word line 206, one of the source and drain of the transistor 202 may be coupled to the bit line 208, the other of the source and drain of the transistor 202 may be coupled to one electrode of the capacitor 204, and the other electrode of the capacitor 204 may be grounded.

In some implementations, since a leakage of a small amount of charges always occurs in the transistor 202, the capacitor 204 will slowly discharge, resulting in poor stability of the memory cell 200. Therefore, memory cells in the memory array 104 shall be periodically refreshed by the peripheral circuit 102 to ensure the stability of memory cells.

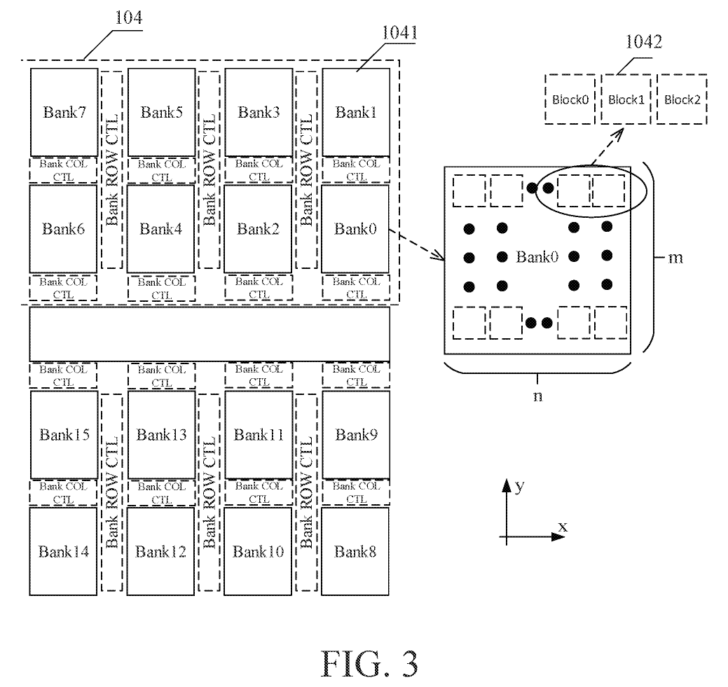

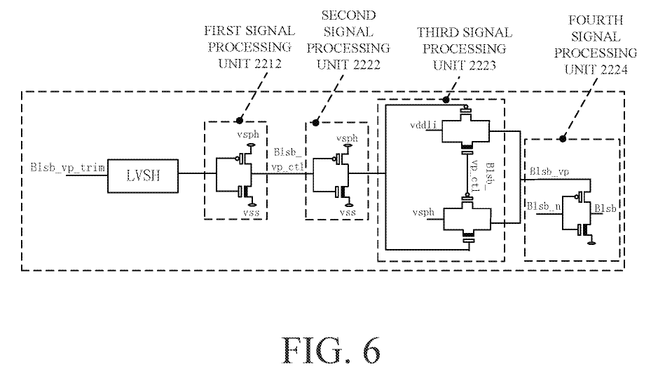

FIG. 3 shows a schematic plan view of a memory array 104. As shown in FIG. 3, the memory device 100 may include one or more memory arrays 104. Each memory array 104 may include a plurality of memory banks 1041, and each memory bank 1041 may further include a plurality of memory blocks 1042. In one example, a memory array 104 may include 8 memory banks 1041, and each memory bank 1041 may include a plurality of memory blocks 1042. As shown in FIG. 6, the memory bank 1041 may include m (in the word line/x direction) x n (in the bit line/y direction) memory blocks 1042.

In order to improve the overall operating speed of the memory device, reading, programming, or erasing operations may be performed on different memory arrays 104 independently. In some implementations, to achieve independent operations, the memory device 100 may include a plurality of peripheral circuits 102, each of which may correspond to one memory array 104. The peripheral circuits 102 may include word line drivers, X decoders, bit line sense amplifiers, pre-charging voltage drivers, discharging voltage drivers, etc. In one example, the memory array 104 may be stacked above or below the peripheral circuits 102. Memory banks 1041 or memory blocks 1042 included in the memory array 104 may partially overlap with the peripheral circuits 102.

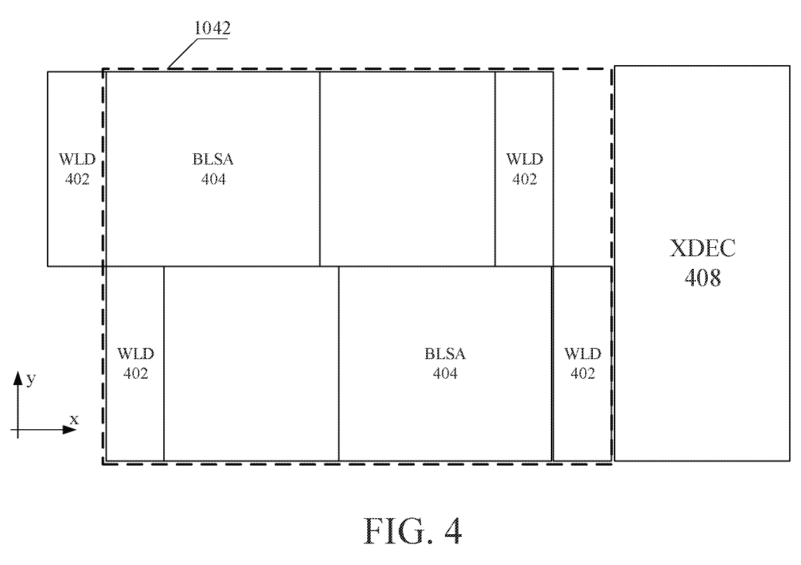

FIG. 4 shows a schematic plan view of a memory block 1042 partially overlapping with a peripheral circuit 102. As shown in FIG. 4, the peripheral circuit that operates and corresponds to the memory block 1042 may include a word line driver (WLD) 402 coupled to a word line of the memory block 1042, and a bit line sense amplifier (BLSA) 404 coupled to a bit line of the memory block 1042. The word line driver 402 may drive the word line by applying operation voltages corresponding to various operations to the word line. The word line driver 402 may include one or more string drivers, and each string driver may include one or more transistors. The bit line sense amplifier 404 may be configured to detect and amplify a current signal in the bit line. As shown in FIG. 4, the memory block 1042 included in the memory array 104 may overlap or partially overlap with the word line driver 402 and the bit line sense amplifier 404 in a vertical direction, where the dashed line in FIG. 4 represents the stacked memory block 1042. In FIG. 4, a stacked manner is shown in which only one memory block 1042 is stacked with its corresponding word line driver 402 and bit line sense amplifier 404. A plurality of memory blocks 1042 and their corresponding word line drivers 402 and bit line sense amplifiers 404, as shown in FIG. 4, may be included in one memory bank 1041, and may be arranged in the x and y directions.

In one example, the peripheral circuit further includes an X decoder (XDEC) 408, which may be arranged in a region which does not overlap with the memory block 1042. The X decoder 408 may perform operations such as decoding row addresses, activating rows, pre-charging, etc. Each X decoder 408 may be configured to operate a row of memory blocks 1042 in the memory bank 1041. The X decoder 408 is located in a region that does not overlap with the memory bank 1041 and the memory block 1042, and for example, may be located in a region that overlaps with a region between two adjacent memory banks 1041, e.g., in the region where a row control circuit (Bank ROW CTL) for the memory bank in FIG. 3 is located.

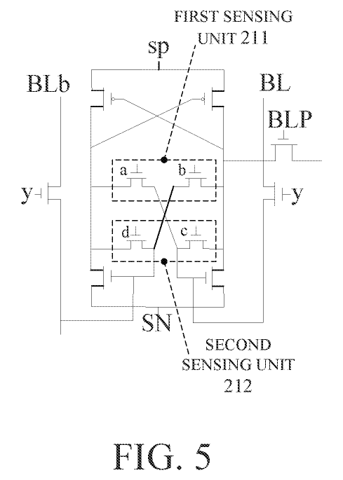

FIG. 5 is a schematic diagram of a bit line sense amplifier provided in an implementation of the present disclosure. As shown in FIG. 5, the bit line sense amplifier includes two sensing units, which may be referred to as a first sensing unit 211 and a second sensing unit 212, respectively, in implementations of the present disclosure. In one example, the first sensing unit 211 may include transistors a and b, and the second sensing unit 212 may include transistors c and d. The sources or drains of transistors a and c are connected, and the sources or drains of transistors b and d are connected. Continuing to refer to FIG. 5, the remaining source or drain of each of transistors a to d may be connected to a bit line (BL) and a bit line bar (BLb) through other transistors, and data may be sensed by the voltage difference between the bit line and the bit line bar.

The gates of transistors included in the first sensing unit 211 or the second sensing unit 212 may be driven by a driving circuit for the bit line sensing amplifier. In one example, the driving circuit for the bit line sense amplifier includes a first driving circuit 22 and a second driving circuit 23, wherein the first driving circuit 22 may be configured to drive transistors in the first sensing unit 211, and the second driving circuit 23 may be configured to drive transistors in the second sensing unit 212. FIG. 6 is a schematic diagram of a driving circuit for a bit line sense amplifier provided in an implementation of the present disclosure. As shown in FIG. 6, the driving circuit includes a level shifter (LVSH) and a plurality of signal processing units, such as a first signal processing unit 2212 directly connected to the output terminal of the level shifter, a second signal processing unit 2222 and a third signal processing unit 2223 respectively connected to the output terminal of the first signal processing unit 2212, and a fourth signal processing unit 2224 connected to the output terminal of the third signal processing unit 2223.

As shown in FIG. 6, the first signal processing unit 2212 includes a pair of transistors, namely a PMOS transistor and an NMOS transistor. The gate of each of PMOS transistor and NMOS transistor is the input terminal of the first signal processing unit 2212, and is connected to the output terminal of the level shifter. The first electrode of the PMOS transistor receives a high level Vsph, the first electrode of the NMOS transistor receives a low level Vss, and the second electrode of the PMOS transistor is connected to the second electrode of the NMOS transistor as the output terminal of the first signal processing unit 2212. In the implementations of the present disclosure, the signal output from the first signal processing unit 2212 may be referred to as Blsb_vp_ctl, and the first and second electrodes may represent the source or drain of the transistor.

The structure of the second signal processing unit 2222 is similar to that of the first signal processing unit 2212. The second signal processing unit 2222 includes a pair of transistors, namely a PMOS transistor and an NMOS transistor. The gate of each of PMOS and NMOS transistors is the input terminal of the second signal processing unit 2222, and is connected to the output terminal of the first signal processing unit 2212. The first electrode of the PMOS transistor receives a high level Vsph, the first electrode of the NMOS transistor receives a low level Vss, and the second electrode of the PMOS transistor is connected to the second electrode of the NMOS transistor as the output terminal of the second signal processing unit 2222.

The third signal processing unit 2223 includes two pairs of transistors, wherein the first pair of transistors includes a PMOS transistor and an NMOS transistor. The gates of PMOS and NMOS transistors are respectively the input terminals of the third signal processing unit 2223, the gate of PMOS transistor is connected to the output terminal of the second signal processing unit 2222, and the gate of NMOS transistor is connected to the output terminal of the first signal processing unit 2212 (as shown directly in FIG. 6). The first electrode of each of the PMOS and NMOS transistors receives Vdd1i, and the second electrodes of the PMOS and NMOS transistors are an output terminal of the third signal processing unit 2223. The second pair of transistors includes a PMOS transistor and an NMOS transistor. The gates of the PMOS and NMOS transistors are also the input terminals of the third signal processing unit 2223. The gate of the PMOS transistor is connected to the output terminal of the first signal processing unit 2212, and the gate of the NMOS transistor is connected to the output terminal of the second signal processing unit 2222. The first electrode of each of PMOS and NMOS transistors receives Vsph, and the second electrodes of the PMOS and NMOS transistors are the output terminal of the third signal processing unit 2223.

The fourth signal processing unit 2224 includes a pair of transistors, namely a PMOS transistor and an NMOS transistor. The gates of the PMOS and NMOS transistors are an input terminal of the fourth signal processing unit 2224, which may receive an external control signal. The first electrode of the PMOS transistor is an input terminal of the fourth signal processing unit 2224, which is connected to the output terminal of the third signal processing unit 2223, and the first electrode of the NMOS transistor receives Vss. The second electrodes of the PMOS and NMOS transistors are the output terminal of the fourth signal processing unit 2224, which may be connected to a control terminal of a first or second sensing unit of a bit line sense amplifier.

In some implementations, the driving circuit for the bit line sense amplifier is integrated into XDEC. As the region occupied by XDEC (hereinafter referred to as XDEC region) is located between memory banks (“between” here means “overlapping with the region between the memory banks”), the larger the area of XDEC region is, the sparser arrangement a plurality of memory banks have, and the lower the storage density of the memory device is. Therefore, how to reduce the area of XDEC region and improve the storage density of the memory device is an urgent problem that needs to be solved.

In addition, in the driving circuit for the bit line sense amplifier, a transistor included in the sensing unit will have a gate leakage current (IDD2), which is a small current that leaks from the gate to the substrate (or source/drain) through a gate oxide layer when the transistor is turned off. The gate leakage current is related to the magnitude of a voltage applied to the gate of the transistor. In one example, the higher the voltage applied to the gate of the transistor is, the higher the gate leakage current is, resulting in higher power consumption of the memory device.

In some implementations, in order to reduce the power consumption impact caused by gate leakage current, a high level with a relatively small voltage value (hereinafter referred to as a second high level) may be applied to the gate of the transistor in the sensing unit during the pre-charging stage in the process of operations on the memory cell, such as reading, writing, etc. The second high level is lower than a high level applied to a gate of a transistor in the sensing unit during a sensing stage or lower than a high level applied to the level shifter. The high level applied to the gate of the transistor in the sensing unit during the sensing stage or the high level applied to the level shifter may be collectively referred to as a first high level.

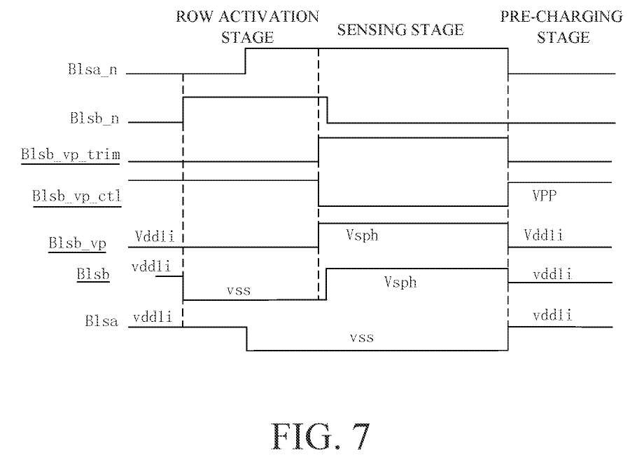

FIG. 7 is a signal schematic diagram of a driving circuit for a bit line sense amplifier. The driving circuit may be the first driving circuit 22 configured to drive the first sensing unit 211 in FIG. 5, or the second driving circuit 23 configured to drive the second sensing unit 212 in FIG. 5. In one example, signal Blsa_n shown in FIG. 7 is a control signal input to the fourth signal processing unit 2224 in the second driving circuit 23. Signal Blsb_n is a control signal input to the fourth signal processing unit 2224 in the first driving circuit 22. Signal Blsb_vp_trim is a control signal input to the level shifter in the first driving circuit 22. Signal Blsb_vp_ctl is an output signal of the first signal processing unit 2212 in the first driving circuit 22, signal Blsb_vp is an output signal of the third signal processing unit 2223, signal Blsb is a driving signal output from the first driving circuit 22, and signal Blsa is a driving signal output from the second driving circuit 23. In FIG. 7, both VPP and Vsph may represent the first high level, and Vdd1i may represent the second high level.

Taking the second driving circuit as an example, during the pre-charging stage, the signal Blsb_vp_trim is at a low level. Therefore, the level shifter outputs a low level, so that the signal Blsb_vp_ctl output from the first signal processing unit 2212 is at a first high level, and the signal output from the second signal processing unit 2222 is at a low level. Referring to FIG. 6, the third signal processing unit 2223 includes two pairs of transistors. The input of the first electrodes of the first pair of transistors is the second high level lower than the first high level. The input of the first electrodes of the second pair of transistors is the first high level. The low level output from the second signal processing unit 2222 is applied to the gate of the PMOS transistor in the first pair of transistors and the gate of the NMOS transistor in the second pair of transistors. The high level output from the first signal processing unit 2212 is applied to the gate of the NMOS transistor in the first pair of transistors and the gate of the PMOS transistor in the second pair of transistors. In this way, both transistors included in the first pair of transistors are turned on, causing the first pair of transistors to output the second high level through the second electrodes, while both transistors included in the second pair of transistors are turned off and do not output a signal. In this way, in response to the signals output from the first signal processing unit 2212 and the second signal processing unit 2222, the signal Blsb_vp output from the third signal processing unit 2223 is at the second high level. In the fourth signal processing unit 2224, the first electrode of the PMOS transistor receives the signal Blsb_vp (second high level), and the gate of the PMOS transistor receives the signal Blsb_n (low level). Therefore, the second electrode of the PMOS transistor in the fourth signal processing unit 2224 will output the second high level, and the NMOS transistor in the fourth signal processing unit 2224 will be turned off and not output signals in response to the low level. In this way, the fourth signal processing unit 2224 outputs the second high level in response to the signal Blsb_vp and signal Blsb_n. For example, during the pre-charging stage, the second driving circuit applies the second high level with a relatively lower voltage value to the transistors in the second sensing unit, which may reduce the gate leakage current of the transistors and thus lower the power consumption of the memory device.

The input and output signals related to the first driving circuit 22 are similar to those of the second driving circuit 23, and will not be repeated in the implementations of the present disclosure. It may be seen that both the level shifters and the fourth signal processing unit 2224 of the first driving circuit 22 and the second driving circuit 23 require external control signals. In this way, each driving circuit requires to receive two external control signals, which will increase the line overhead of the memory device and thus increase the cost of the memory device.

A memory device and a corresponding control method provided by implementations of the present disclosure, on one hand, may reduce the area of XDEC region and improve the storage density of the memory device, and on the other hand, may reduce the gate leakage current which occurs in the driving circuit for the bit line sense amplifier, and also reduce the corresponding line overhead, and save the cost of the memory device.

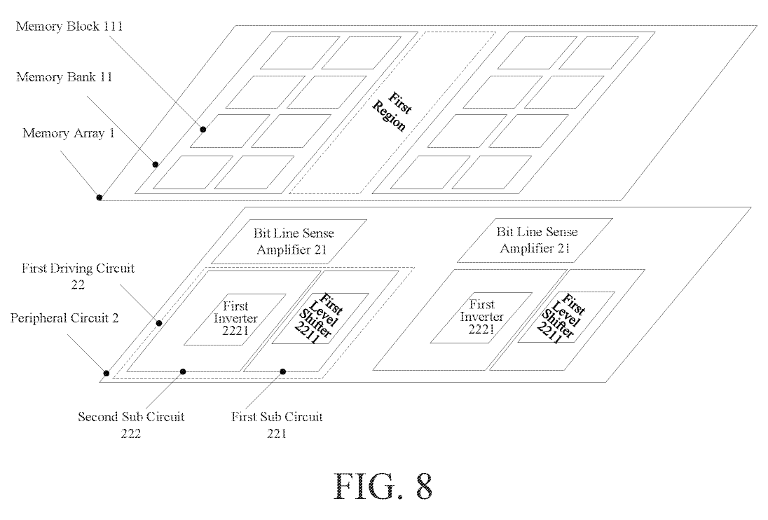

FIG. 8 is a schematic structural diagram of a memory device provided in an implementation of the present disclosure. As shown in FIG. 8, the memory device includes a memory array 1 and a peripheral circuit 2 which are stacked together. The memory array 1 includes a plurality of memory banks 11, and a memory bank 11 includes a plurality of memory blocks 111. The memory bank 11 is the memory bank in implementations described above, and the memory block 111 is a memory block in implementations described above.

The peripheral circuit 2 includes a plurality of bit line sense amplifiers 21, and a first driving circuit 22 connected to the plurality of bit line sense amplifiers 21, respectively. The first driving circuit 22 includes a first sub circuit 221 and at least one second sub circuit 222. The first sub circuit 221 includes a first level shifter 2211, the second sub circuit 222 includes a first inverter 2221, the second sub circuit 222 overlaps with the memory blocks 111 in a stacking direction, and the first sub circuit 221 overlaps with the first region in the memory array 1 in the stacking direction, where the first region is a region between the memory banks 11.

In the implementations of the present disclosure, the first inverter 2221 may refer to the first signal processing unit 2212, the second signal processing unit 2222, the third signal processing unit 2223, or the fourth signal processing unit 2224 in implementations described above.

When the first inverter 2221 is the first signal processing unit 2212, the second sub circuit 222 includes the first signal processing unit 2212, the second signal processing unit 2222, the third signal processing unit 2223, and the fourth signal processing unit 2224.

When the first inverter 2221 is the second signal processing unit 2222, the second sub circuit 222 includes at least the second signal processing unit 2222, the third signal processing unit 2223, and the fourth signal processing unit 2224. In this case, the first signal processing unit 2212 may be located in the first sub circuit 221 or in the second sub circuit 222.

When the first inverter 2221 is the third signal processing unit 2223, the second sub circuit 222 includes at least the third signal processing unit 2223 and the fourth signal processing unit 2224. In this case, the first signal processing unit 2212 and the second signal processing unit 2222 may be located in the first sub circuit 221 or in the second sub circuit 222, or the first signal processing unit 2212 may be located in the first sub circuit 221 and the second signal processing unit 2222 may be located in the second sub circuit 222.

When the first inverter 2221 is the fourth signal processing unit 2224, the second sub circuit 222 includes at least the fourth signal processing unit 2224. In this case, the first signal processing unit 2212, the second signal processing unit 2222, and the third signal processing unit 2223 may be located in the first sub circuit 221 or in the second sub circuit 222, or the first signal processing unit 2212, the second signal processing unit 2222, and the third signal processing unit 2223 may be arranged in the first sub circuit 221 and the second sub circuit 222.

In one example, the first inverter 2221 is a signal processing unit that receives an external data signal (such as signal Blsb_n). For example, the first inverter 2221 is the fourth signal processing unit 2224. The first sub circuit 221 may include a first level shifter 2211 and a first signal processing unit 2212. The second sub circuit 222 includes a second signal processing unit 2222, a third signal processing unit 2223, and a first inverter 2221.

For example, in the implementations of the present disclosure, the driving circuit for the bit line sense amplifier 21 may be divided into two parts, so that one part of the circuit is the first sub circuit 221 including the first level shifter 2211, and the other part of the circuit is the second sub circuit 222 including the first inverter 2221. The first sub circuit 221 is located in the XDEC region, while the second sub circuit 222 is located in the region overlapping with the memory blocks 111. In this way, the area occupied by the XDEC region may be reduced, thereby reducing the region between memory banks 11 and improving the storage density of the memory device.

In an implementation of the present disclosure, the first driving circuit 22 includes a plurality of second sub circuits 222. Input terminals of the plurality of second sub circuits 222 are respectively connected to an output terminal of the first sub circuit 221, and an output terminal of each of the second sub circuits 222 may be respectively connected to a driving terminal of a bit line sense amplifier 21. For example, the second sub circuits 222 may have a one-to-one correspondence relationship with the driving terminals of the bit line sense amplifiers 21.

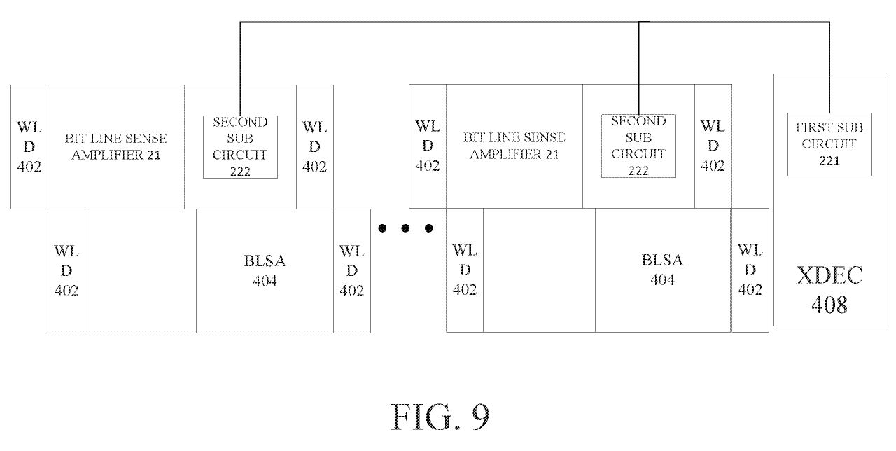

As seen from FIG. 4, in the region of the peripheral circuit 2 overlapping with the memory blocks 111, in addition to circuits such as bit line sense amplifier 21, there is also a free region, which is located between BLSA 404 and WLD 402 in the x-direction. Therefore, in the implementations of the present disclosure, the second sub circuit 222 is located within the free region. FIG. 9 is a planar arrangement diagram of a first sub circuit 221 and a second sub circuit 222 provided in an implementation of the present disclosure. Since the region of the peripheral circuit 2 overlapping with each of the memory blocks 111 includes a free region, there may be a second sub circuit 222 matching with each of the memory blocks 111 in the implementations of the present disclosure. For example, the first driving circuit may include a first sub circuit 221 and a plurality of second sub circuits 222, and the number of the plurality of second sub circuits 222 is equal to the number of memory blocks 111 in one row of memory blocks 111 of the memory bank 11. In one example, a memory block 111 may correspond to a plurality of bit line sense amplifiers 21, and the number of the plurality of bit line sense amplifiers 21 may be equal to the number of bit lines connected to the memory block 111. A second sub circuit 222 may be configured to drive the plurality of bit line sense amplifiers 21 corresponding to a memory block 111, e.g., to drive the sensing units respectively included in the plurality of bit line sense amplifiers 21, such as the first sensing unit 211. In this way, on one hand, the area occupied by the XDEC region is reduced, and the storage density of the memory device is improved. On the other hand, by making reasonable use of the free regions in the memory device and allocating a second sub circuit 222 to each bit line sense amplifier 21, the driving capability of each bit line sense amplifier 21 may be improved, thereby enhancing the stability of the memory device.

Continuing to refer to FIG. 9, for a plurality of bit line sense amplifiers 21 connected to the same first driving circuit 22, the memory blocks 111 respectively connected to the plurality of bit line sense amplifiers 21 are the memory blocks 111 located in the same row in the memory bank 11. In this way, for XDEC, memory blocks 111 can still be controlled by row without the need for software adaptation.

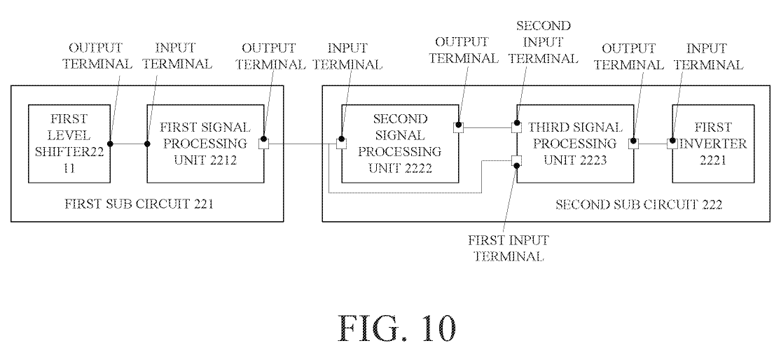

In an example, as shown in FIG. 10, the first inverter 2221 refers to the fourth signal processing unit 2224, and the first sub circuit 221 includes a first level shifter 2211 and a first signal processing unit 2212. The input terminal of the first signal processing unit 2212 is connected to the output terminal of the first level shifter 2211. The second sub circuit 222 includes a second signal processing unit 2222, a third signal processing unit 2223, and a first inverter 2221. The input terminal of the second signal processing unit 2222 and the first input terminal of the third signal processing unit 2222 are connected to the output terminal of the first signal processing unit 2212, the output terminal of the second signal processing unit 2222 is connected to the second input terminal of the third signal processing unit 2223, and the output terminal of the third signal processing unit 2223 is connected to the input terminal of the first inverter 2221.

In this case, the first level shifter 2211 only needs to drive one first signal processing unit 2212, so the driving capability requirement for the first level shifter 2211 is relatively low. Therefore, the size of the first level shifter 2211 may be relatively small, further reducing the area of the XDEC region.

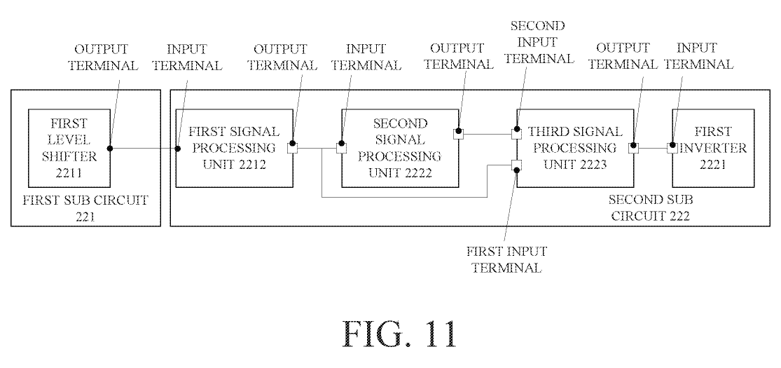

In another example, as shown in FIG. 11, the first inverter 2221 refers to the fourth signal processing unit 2224, and the first sub circuit 221 only includes a first level shifter 2211. The second sub circuit 222 includes a first signal processing unit 2212, a second signal processing unit 2222, a third signal processing unit 2223, and a first inverter 2221. The input terminal of the first signal processing unit 2212 is connected to the output terminal of the first level shifter 2211 in the first sub circuit 221, the input terminal of the second signal processing unit 2222 and the first input terminal of the third signal processing unit 2222 are connected to the output terminal of the first signal processing unit 2212, the output terminal of the second signal processing unit 2222 is connected to the second input terminal of the third signal processing unit 2223, and the output terminal of the third signal processing unit 2223 is connected to the input terminal of the first inverter 2221.

In this case, since each of the signal processing units is located in the overlapping area with the memory block 111, the area of the XDEC region is further reduced, thereby increasing the storage density of the memory device. In addition, since the first level shifter 2211 only needs to drive a plurality of first signal processing units 2212, a first level shifter 2211 with higher driving capability may be selected in this case.

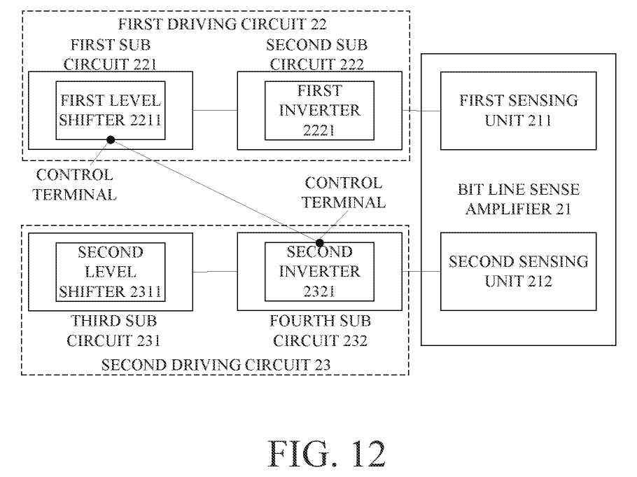

The above implementations introduce the content related to the first driving circuit 22. By dividing the first driving circuit 22 into a first sub circuit 221 and a second sub circuit 222 and disposing the second sub circuit 222 in the overlapping region with the memory block 111, the storage density of the memory device may be improved. The memory device further includes a second driving circuit 23 configured to drive the second sensing unit 212 in the bit line sense amplifier 21. Similarly, as shown in FIG. 12, the second driving circuit 23 includes a third sub circuit 231 and at least one fourth sub circuit 232. The third sub circuit 231 includes a second level shifter 2311, and the fourth sub circuit 232 includes a second inverter 2321. Correspondingly, the second inverter 2321 may be a processing unit of the second driving circuit 23, to which an external control signal is input.

For the third sub circuit 231 and the fourth sub circuit 232 included in the second driving circuit 23, the third sub circuit 231 includes the second level shifter 2311, and the fourth sub circuit 232 includes the second inverter 2321. In one example, the third sub circuit 231 is located in the XDEC region, and the fourth sub circuit 232 is located in the region overlapping with the memory block 111. In this way, the area occupied by the XDEC region is reduced, thereby reducing the region between memory banks 11 and further improving the storage density of the memory device. In another example, both the third sub circuit 231 and the fourth sub circuit 232 may not overlap with the memory blocks 111, for example, they are both located in the XDEC region. For example, in the implementations of the present disclosure, as long as one of the second sub circuit 222 in the first driving circuit 22 and the fourth sub circuit 232 in the second driving circuit 23 is located in the overlapping region with the memory blocks 111, the area occupied by the XDEC region may be reduced, thereby achieving an increase in the storage density of the memory device.

Regarding the detailed introduction of the third sub circuit 231 and the fourth sub circuit 232, similar to the first sub circuit 221 and the second sub circuit 222, please refer to the introduction of the first sub circuit 221 and the second sub circuit 222 in the above implementations, which will not be repeated here.

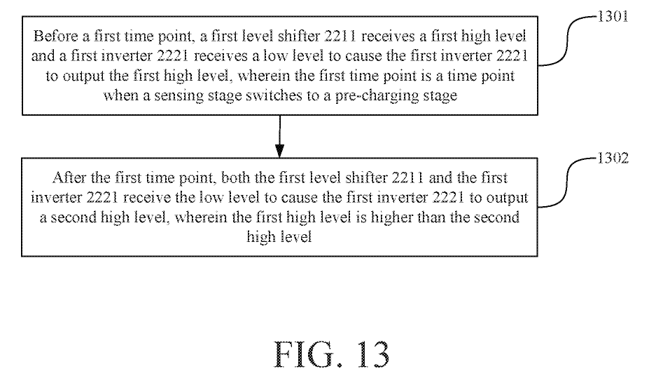

On the basis of FIG. 12, an implementation of the present disclosure further provides a method of controlling a memory device that may reduce the gate leakage current which occurs in the bit line sense amplifier. FIG. 13 is a flowchart of a control method provided in an implementation of the present disclosure. As shown in FIG. 13, the control method includes: operation 1301: before a first time point, the first level shifter 2211 receives a first high level and the first inverter 2221 receives a low level to cause the first inverter 2221 to output the first high level, wherein the first time point is a time point when a sensing stage switches to a pre-charging stage; and operation 1302: after the first time point, both the first level shifter 2211 and the first inverter 2221 receive the low level to cause the first inverter 2221 to output a second high level, wherein the first high level is higher than the second high level.

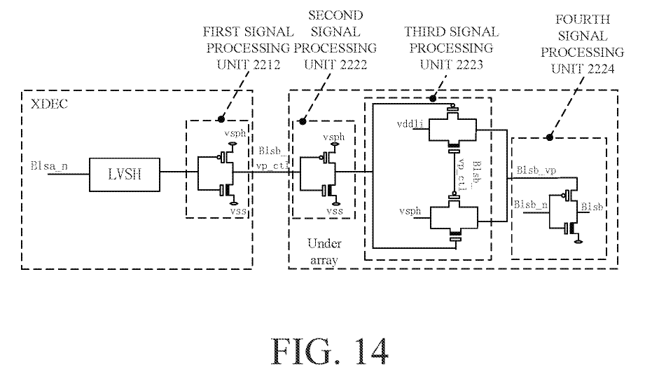

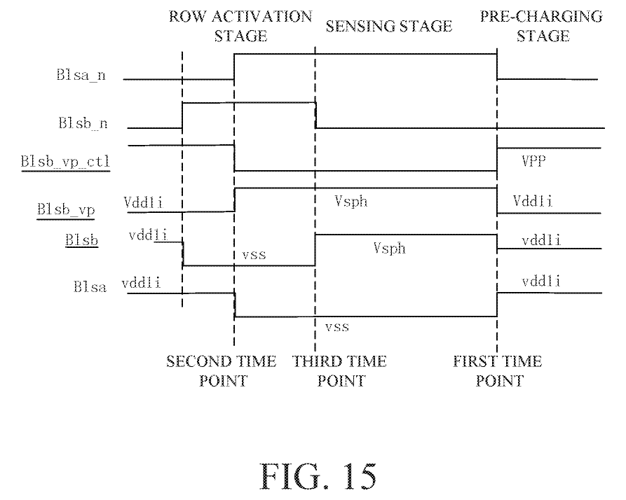

The control method including operations 1301 and 1302 may be applied to the driving circuit shown in FIG. 6, or to the driving circuit shown in FIG. 14. Regarding the corresponding signal processing processes, please refer to the signal diagram shown in FIG. 7 or to the signal diagram shown in FIG. 15. When the control method including operations 1301 and 1302 is applied to the driving circuit shown in FIG. 6 or in FIG. 14, in operations 1301 and 1302, the first level shifter 2211 refers to LVSH shown in FIG. 6 or FIG. 14, and the first inverter 2221 refers to the fourth signal processing unit 2224 shown in FIG. 6 or FIG. 14.

As shown in FIG. 7, the process of reading/writing data from/to memory cells in the memory device may be divided into three stages, including a row activation stage, a sensing stage, and a pre-charging stage. The three stages may occur alternately and cyclically in sequence. The first time point in the implementations of the present disclosure refers to a time point when the sensing stage switches to the pre-charging stage. For example, in the sensing stage, the input terminal of the first level shifter 2211 receives a first high level, such as the signal Blsb_vp_trim shown in FIG. 7. The first inverter 2221 receives a low level, such as the signal Blsb_n in FIG. 7, to cause the first driving circuit 22 to apply a first high level to the first sensing unit 211 included in the bit line sense amplifier 21. In the pre-charging stage, the input terminal of the first level shifter 2211 receives a low level, and the first inverter 2221 also receives a low level to cause the first driving circuit 22 to apply a second high level to the first sensing unit 211 included in the bit line sense amplifier 21. In this way, the high level applied to the first sensing unit 211 during the pre-charging stage is relatively low, which may reduce the leakage current of the transistors in the first sensing unit 211 and reduce the power consumption of the memory device.

In some examples, the implementations of the present disclosure provides a new control method for the first driving circuit 22. As shown in FIG. 12, the control terminal of the first level shifter 2211 included in the first driving circuit 22 is connected to the control terminal of the second inverter 2321 included in the second driving circuit 23.

The control terminal of the first level shifter 2211 and the control terminal of the second inverter 2321 each are terminals for receiving external control signals. For example, in FIG. 7, the control terminal of the first level shifter 2211 is a terminal for receiving Blsb_vp_trim. The control terminal of the second inverter 2321 is a terminal for receiving the signal Blsa_n. Unlike FIG. 7, in the implementations of the present disclosure, the control terminal of the first level shifter 2211 is connected to the control terminal of the second inverter 2321. For example, the input signal of the control terminal of the first level shifter 2211 is the input signal of the control terminal of the second inverter 2321, which is the signal Blsa_n. In this way, like FIG. 7, during the sensing stage before the first time point, the input terminal of the level shifter 2211 receives a first high level, and the first inverter 2221 receives a low level; and during the sensing stage after the first time point, the input terminal of the level shifter 2211 receives a low level, and the first inverter 2221 receives a low level, thereby reducing the power consumption of the memory device during the pre-charging stage.

It may be seen that in the implementations of the present disclosures, the first level shifter 2211 in the first driving circuit 22 and the second inverter 2321 in the second driving circuit 23 may be controlled by one control signal, such as the signal Blsa_n. In this way, the first driving circuit 22 and the second driving circuit 23 only need three control signals, so that the power consumption of the memory device may be reduced while ensuring the normal driving of sensing units. In this way, the line overhead of control signals is reduced and the cost of the memory device is saved.

FIG. 14 is a schematic diagram of a first driving circuit provided in an implementation of the present disclosure. Unlike FIG. 6, in FIG. 14, the first level shifter 2211 and the first signal processing unit 2212 in the driving circuit are located in the XDEC region, and the second to fourth signal processing units 2222 to 2224 are located in the overlapping region with the memory blocks. The input of the first level shifter 2211 is the control signal of the second inverter 2321 in the second driving circuit 23, e.g., Blsa_n.

FIG. 15 is a schematic diagram of a control signal provided by an implementation of the present disclosure. The control method provided by the implementations of the present disclosure will be further described below in conjunction with FIGS. 12 to 15.

In the implementations of the present disclosure, a first time point, a second time point, and a third time point are involved. The first time point is a time point when a sensing stage switches to a pre-charging stage, the second time point is a time point within a row activation stage, and the third time point is a time point when the row activation stage switches to the sensing stage. The specific position of the second time point within the row activation stage may be pre-set by the technician, which is not exemplified in the implementations of the present disclosure. Taking the second time point, the third time point and the first time point in sequence as an example, the approach is described below.

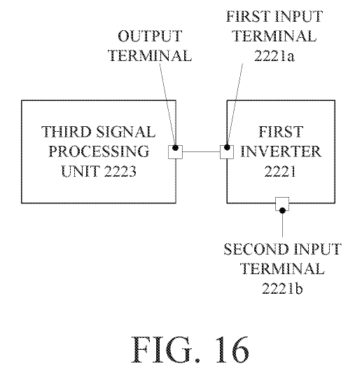

Before the second time point, the first level shifter 2211 receives a low level to cause the second signal processing unit 2222 to output a first high level, and the third signal processing unit 2223 to output a second high level. After the second time point, the first level shifter receives a first high level to cause the second signal processing unit 2222 to output a low level and the third signal processing unit 2223 to output the first high level. As shown in FIG. 16, the output terminal of the third signal processing unit 2223 may be connected to the first input terminal 2221a of the first inverter 2221, and the second input terminal 2221b of the first inverter 2221 may receive an external control signal, such as the signal Blsb_n.

As shown in FIGS. 14 and 15, during the row activation stage and before the second time point, the input (signal Blsa_n) of the first level shifter 2211 is at a low level, and the output is also at a low level. At this time, the input of the first signal processing unit 2212 is at a low level, the output (signal Blsb_vp_ctl) of the first signal processing unit 2212 is at a first high level, and the output of the second signal processing unit 2222 is at a low level. In this way, in response to the output of the first signal processing unit 2212 and the output of the second signal processing unit 2222, transistors of the four transistors in the third signal processing unit 2223 connected to the second high level (Vdd1i) are turned on, so that the output signal (signal Blsb_vp) of the third signal processing unit 2223 is Vdd1i. However, since the input (signal Blsb_n) of the first inverter 2221 is at a high level, the conduction of Vdd1i inside the first inverter 2221 is blocked, and thus the signal (signal Blsb) output from the first inverter 2221 is at a low level (Vss).

In the row activation stage and after the second time point, the input (signal Blsa_n) of the first level shifter 2211 transitions from a low level to a high level, and the output thereof is also at a high level. At this time, the input of the first signal processing unit 2212 is at a high level, the output (signal Blsb_vp_ctl) of the first signal processing unit 2222 is at a low level, and the output of the second signal processing unit 2222 is at a high level. In this way, in response to the output of the first signal processing unit 2212 and the output of the second signal processing unit 2222, transistors of the four transistors in the third signal processing unit 2223 connected to a high level (Vsph) is turned on, so that the output signal (signal Blsb_vp) of the third signal processing unit 2223 is Vsph. Since the input (signal Blsb_n) of the first inverter 2221 is still at a high level, the conduction of Vsph inside the first inverter 2221 is blocked, and thus the signal (signal Blsb) output from the first inverter 2221 remains at a low level.

Before the third time point, the first level shifter 2211 receives a first high level, and the first inverter 2221 receives a first high level to cause the first inverter 2221 to output a low level. The third time point is a time point when the row activation stage switches to a sensing stage. After the third time point, the first level shifter 2211 receives a first high level, and the first inverter 2221 receives a low level to cause the first inverter 2221 to output the first high level.

As shown in FIGS. 14 and 15, the situation before the third time point is the same as the situation after the second time point, and thus will not be further described. After the third time point, e.g., during the sensing stage, the input (signal Blsa_n) of the first level shifter 2211 remains unchanged and remains at a high level. Therefore, the output signal (signal Blsb_vp) of the third signal processing unit 2223 is still Vsph. However, since the input (signal Blsb_n) of the first inverter 2221 is at a low level, the Vsph output from the third signal processing unit 2223 conducts inside the first inverter 2221. Therefore, in the sensing stage, the signal (signal Blsb) output from the first inverter 2221 is Vsph.

Before the first time point, the first level shifter 2211 receives a first high level to cause the third signal processing unit 2223 to output the first high level to the first input terminal 2221a. The first inverter 2221 receives a low level through the second input terminal 2221b and outputs a first high level in response to receiving the first high level at the first input terminal 2221a. After the first time point, the first level shifter 2211 receives a low level to cause the third signal processing unit 2223 to output the second high level to the first input terminal 2221a. The first inverter 2221 receives a low level through the second input terminal 2221b and outputs a second high level in response to receiving the second high level at the first input terminal 2221a.

The situation before the first time point is the same as the situation after the third time point, and thus will not be further described. After the first time point, e.g., during the pre-charging stage, the input (signal Blsa_n) of the first level shifter 2211 is at a low level. Therefore, the output signal (signal Blsb_vp) of the third signal processing unit 2223 is Vdd1i. However, since the input (signal Blsb_n) of the first inverter 2221 remains unchanged, the Vdd1i output from the third signal processing unit 2223 conducts inside the first inverter 2221. Therefore, during the pre-charging stage, the signal (signal Blsb) output from the first inverter 2221 is Vdd1i.

Based on the relevant implementations described above with reference to FIGS. 12 to 16, in the implementations of the present disclosure, by connecting the control signal of the second inverter of the second driving circuit to the first level shifter of the first driving circuit, on the one hand, the line overhead of the memory device is reduced, and on the other hand, the gate leakage current in the bit line sense amplifier may be reduced during the pre-charging stage, thereby reducing the power consumption of the bit line sense amplifier.

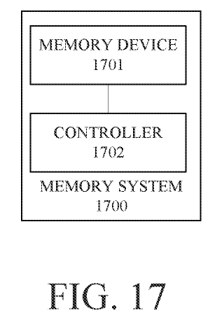

FIG. 17 is a schematic structural diagram of a memory system provided in an implementation of the present disclosure. The memory system 1700 includes a memory device 1701 as described in the above implementations, such as the memory device shown in FIG. 8, and further includes a controller 1702 configured to control the memory device, such as a controller configured to write/read data to/from the memory device.

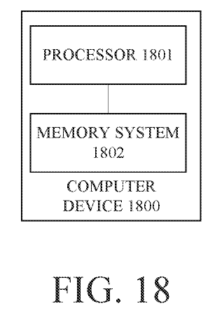

FIG. 18 is a schematic structural diagram of a computer device provided in an implementation of the present disclosure. The computer device 1800 may be a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device with a storage therein. As shown in FIG. 18, the computer device 1800 may include a processor 1801. In one example, the processor 1801 may be a central processing unit (CPU) or a system on chip (SoC), and configured to send data to the memory system 1802 or receive data from the memory system 1802.

In the present disclosure, the terms “first”, “second”, or the like, are only used for an illustrative purpose, and should not be construed as indicating or implying a relative importance. The term “at least one” refers to one or more, and the term “a plurality of” refers to two or more, unless otherwise specified.

The above are only exemplary implementations of the present disclosure and not intended to limit the present disclosure. Any modifications, equivalent substitutions, improvements, etc., made within the spirit and principles of the present disclosure shall be included in the scope of the present disclosure.

What is claimed is:

1. A memory device, comprising a memory array and a peripheral circuit which are stacked together, wherein:
the memory array comprises a plurality of memory banks, wherein each memory bank of the plurality of memory banks comprises a plurality of memory blocks; and
the peripheral circuit comprises a plurality of bit line sense amplifiers and a first driving circuit connected to the plurality of bit line sense amplifiers, wherein the first driving circuit comprises a first sub circuit and at least one second sub circuit, wherein the first sub circuit comprises a first level shifter, wherein the second sub circuit comprises a first inverter, and wherein the second sub circuit overlaps with a memory block of the plurality of memory blocks in a stacking direction.

2. The memory device of claim 1, wherein the first sub circuit overlaps with a first region in the memory array in the stacking direction, and wherein the first region is a region between the memory banks.

3. The memory device of claim 1, wherein the at least one second sub circuit comprises a plurality of second sub circuits, wherein input terminals of the plurality of second sub circuits are connected to an output terminal of the first sub circuit, and wherein an output terminal of each of the second sub circuits is connected to a driving terminal of a respective bit line sense amplifier of the plurality of bit line sense amplifiers.

4. The memory device of claim 3, wherein for the plurality of bit line sense amplifiers connected to the same first driving circuit, memory blocks respectively connected to the plurality of bit line sense amplifiers are memory blocks located in the same row in the memory bank.

5. The memory device of claim 1, wherein:
the peripheral circuit further comprises a second driving circuit connected to the plurality of bit line sense amplifiers, wherein each bit line sense amplifier of the plurality of bit line sense amplifiers comprises a first sensing unit and a second sensing unit, wherein the first driving circuit is configured to drive the first sensing unit, and wherein the second driving circuit is configured to drive the second sensing unit; and
the second driving circuit comprises a third sub circuit and at least one fourth sub circuit, wherein the third sub circuit comprises a second level shifter, wherein the fourth sub circuit comprises a second inverter, and wherein a control terminal of the first level shifter comprised in the first driving circuit is connected to a control terminal of the second inverter comprised in the second driving circuit.

6. The memory device of claim 5, wherein the first driving circuit is configured so that:
before a first time point, the first level shifter receives a first high level and the first inverter receives a low level to cause the first inverter to output the first high level, wherein the first time point is a time point when a sensing stage switches to a pre-charging stage; and
after the first time point, both the first level shifter and the first inverter receive the low level to cause the first inverter to output a second high level, wherein the first high level is higher than the second high level.

7. The memory device of claim 1, wherein the first sub circuit further comprises a first signal processing unit, wherein an input terminal of the first signal processing unit is connected to an output terminal of the first level shifter, and the first signal processing unit comprises a pair of transistors in parallel; and
the second sub circuit further comprises a second signal processing unit and a third signal processing unit, wherein an input terminal of the second signal processing unit and a first input terminal of the third signal processing unit are connected to an output terminal of the first signal processing unit, wherein an output terminal of the second signal processing unit is connected to a second input terminal of the third signal processing unit, wherein an output terminal of the third signal processing unit is connected to an input terminal of the first inverter, t wherein he second signal processing unit comprises a pair of transistors in parallel, and wherein the third signal processing unit comprises two pairs of transistors, each pair of which has transistors in parallel.

8. The memory device of claim 1, wherein the second sub circuit further comprises a first signal processing unit, a second signal processing unit, and a third signal processing unit, wherein an input terminal of the first signal processing unit is connected to an output terminal of the first level shifter in the first sub circuit, wherein an input terminal of the second signal processing unit and a first input terminal of the third signal processing unit are connected to an output terminal of the first signal processing unit, wherein an output terminal of the second signal processing unit is connected to a second input terminal of the third signal processing unit, wherein an output terminal of the third signal processing unit is connected to an input terminal of the first inverter, wherein the first signal processing unit comprises a pair of transistors in parallel, wherein the second signal processing unit comprises a pair of transistors in parallel, and wherein the third signal processing unit comprises two pairs of transistors, each pair of which has transistors in parallel.

9. The memory device of claim 1, wherein the memory device comprises a dynamic random access memory (DRAM).

10. A method of controlling a memory device comprising a memory array and a peripheral circuit, wherein the memory array comprises a plurality of memory banks, wherein each memory bank of the plurality of memory banks comprises a plurality of memory blocks, wherein the peripheral circuit comprises a plurality of bit line sense amplifiers and a first driving circuit connected to the plurality of bit line sense amplifiers, wherein the first driving circuit comprises a first sub circuit and at least one second sub circuit, wherein the first sub circuit comprises a first level shifter, wherein the second sub circuit comprises a first inverter, and
wherein the method comprises:
before a first time point, the first level shifter receiving a first high level and the first inverter receiving a low level to cause the first inverter to output the first high level, wherein the first time point is a time point when a sensing stage switches to a pre-charging stage; and
after the first time point, both the first level shifter and the first inverter receiving the low level to cause the first inverter to output a second high level, wherein the first high level is higher than the second high level.

11. The method of claim 10, wherein the first sub circuit further comprises a first signal processing unit, wherein an input terminal of the first signal processing unit is connected to an output terminal of the first level shifter, and wherein the first signal processing unit comprises a pair of transistors in parallel;
wherein the second sub circuit further comprises a second signal processing unit and a third signal processing unit, wherein an input terminal of the second signal processing unit and a first input terminal of the third signal processing unit are connected to an output terminal of the first signal processing unit, wherein an output terminal of the second signal processing unit is connected to a second input terminal of the third signal processing unit, wherein an output terminal of the third signal processing unit is connected to an input terminal of the first inverter, wherein the second signal processing unit comprises a pair of transistors in parallel, and wherein the third signal processing unit comprises two pairs of transistors, each pair of which has transistors in parallel.

12. The method of claim 11, further comprising:
before a second time point, the first level shifter receiving the low level to cause the second signal processing unit to output the first high level and the third signal processing unit to output the second high level, wherein the second time point is within a row activation stage; and
after the second time point, the first level shifter receiving the first high level to cause the second signal processing unit to output the low level and the third signal processing unit to output the first high level.

13. The method of claim 11, wherein the first inverter comprises a first input terminal and a second input terminal, and wherein the first input terminal is connected to the output terminal of the third signal processing unit.

14. The method of claim 13, wherein before the first time point, the first level shifter receiving the first high level and the first inverter receiving the low level to cause the first inverter to output the first high level comprises:
before the first time point, the first level shifter receiving the first high level to cause the third signal processing unit to output the first high level to the first input terminal the first inverter receiving the low level through the second input terminal, and outputting the first high level in response to receiving the first high level at the first input terminal.

15. The method of claim 14, wherein the first level shifter receiving the first high level to cause the third signal processing unit to output the first high level to the first input terminal comprises:
the first level shifter receiving the first high level and outputting the first high level to the first signal processing unit;
the first signal processing unit outputting the low level to the input terminal of the second signal processing unit in response to the input first high level;
the second signal processing unit outputting the first high level to an input terminal of the third signal processing unit in response to the input low level; and
the third signal processing unit outputting the first high level to the first input terminal in response to the input first high level.

16. The method of claim 13, wherein after the first time point, both the first level shifter and the first inverter receiving the low level to cause the first inverter to output the second high level comprises:
after the first time point, the first level shifter receiving the low level to cause the third signal processing unit to output the second high level to the first input terminal; and
the first inverter receiving the low level through the second input terminal and outputting the second high level in response to receiving the second high level at the first input terminal.

17. The method of claim 15, wherein the first level shifter receiving the low level to cause the third signal processing unit to output the second high level to the first input terminal comprises:
the first level shifter receiving the low level and outputting the low level to the first signal processing unit;
the first signal processing unit outputting the first high level to the input terminal of the second signal processing unit in response to the input low level;
the second signal processing unit outputting the low level to the input terminal of the third signal processing unit in response to the input first high level; and
the third signal processing unit outputting the second high level to the first input terminal in response to the input low level.

18. The method of claim 10, further comprising:
before a third time point, the first level shifter receiving the first high level and the first inverter receiving the first high level to cause the first inverter to output the low level, wherein the third time point is a time point when a row activation stage switches to the sensing stage; and
after the third time point, the first level shifter receiving the first high level and the first inverter receiving the low level to cause the first inverter to output the first high level.

19. A memory system, comprising:
a memory device; and
a controller coupled to the memory device and configured to control the memory device, wherein the memory device comprises a memory array and a peripheral circuit which are stacked together, wherein:
the memory array comprises a plurality of memory banks, wherein each memory bank of the plurality of memory banks comprises a plurality of memory blocks; and
the peripheral circuit comprises a plurality of bit line sense amplifiers and a first driving circuit connected to the plurality of bit line sense amplifiers, wherein the first driving circuit comprises a first sub circuit and at least one second sub circuit, wherein the first sub circuit comprises a first level shifter, wherein the second sub circuit comprises a first inverter, and wherein the second sub circuit overlaps with a memory block of the plurality of memory blocks in a stacking direction.
